(19) United States
(12) Patent Application Publication
(10) Pub. No.: US 2011/0102977 A1
(43) Pub. Date: May 5, 2011

(54) Electronic device having a foldable screen

(76) Inventor: Tonny Chen, Shengang Shiang (TW)

(21) Appl. No.: 12/588,987

(22) Filed: Nov. 4, 2009

(51) Int. Cl. H05K 5/00

(52) U.S. Cl. 361/679.01

(57) ABSTRACT

An electronic device having a foldable screen includes a flexible screen, a first chassis and a second chassis. The flexible screen is rectangular and has a stub shaft located thereon for turning. The first chassis has a first side formed a plane to flatly hold the flexible screen and a vertical holding shaft located thereon to couple with the stub shaft. The second chassis has an operation interface. The first and second chassis can be folded together, and the flexible screen can be turned about the coupled stub shaft and vertical holding shaft for 90 degrees to align with lateral sides of the first and second chassis. Then the first and second chassis can be wrapped by the flexible screen along a longer side thereof to facilitate storing without occupying a lot of space.

### BACKGROUND OF THE INVENTION

1. Field of the Invention

The present invention relates to an electronic device having a foldable screen with a first chassis and a second chassis that are foldable and a flexible screen to wrap around the folded chassis to facilitate storing without occupying a lot of space.

2. Description of the Prior Art

Progress of wireless networks makes development of computers (such as personal computers, notebook computers, navigation systems and the like) increasingly focused on portability. As product size directly impacts portability, slim, thin and light have become the prevailing trend of product design. Hence the display screen is made smaller. The smaller display screen makes operation and reading more difficult. Therefore the size of product and screen often is one of key factors in product design. These days advance of display screen technology makes rollable screen (commonly called flexible screen possible. A large screen can be rolled like a barrel to reduce the storing size and make portability of products easier to materialize.

While the rollable screen provides benefit for storing, it has to be incorporated with an operating host when in use. Hence a holding means has to be provided to hold the rollable screen rolled in a barrel fashion. The operating host usually is formed in a flattened and rectangular structure to facilitate operation and data entry. The rolled screen is cylindrical and does not match the rectangular host. Moreover, the rollable screen usually cannot be folded like paper to mate the size of the operating host. As a result, portability of the rollable screen still leaves a lot to be desired.

### SUMMARY OF THE INVENTION

Therefore it is an object of the present invention to provide an electronic device with a foldable screen to allow a portable computer and a rollable flexible screen to be coupled in a smaller size to facilitate carrying. It mainly includes a flexible screen, a first chassis and a second chassis. The flexible screen is rectangular and has two shorter sides and two longer sides, and a stub shaft for turning. The first chassis has a first side formed in a plane to provide flat support for the flexible screen and a vertical holding shaft to couple with the stub shaft. The second chassis has an operation interface. By means of the construction set forth above, the first chassis and the second chassis can be folded together, and the flexible screen can be turned about an axis formed by the coupled stub shaft and the vertical holding shaft for 90 degrees to align with lateral sides of the first and second chassis. Then the first and second chassis can be wrapped by the flexible screen along the longer sides to facilitate storing without occupying a lot of space.

In one aspect of the invention the shorter sides of the flexible screen are formed at a length slightly smaller than the width of the first and second chassis.

In another aspect, the flexible screen has at least a portion bendable more than 90 degrees along the longer sides.

When in use the flexible screen can be unfolded against the first chassis and bonded to a corresponding area formed between them. The corresponding bonding area has at least one anchor element to anchor the flexible screen. The anchor element may be a Velcro band or a latch element.

When in use and the flexible screen being turned 90 degrees in a vertical condition, a vertical display can be formed through control the a computer system. The display portion takes a portion of the area at the longer sides.

The second chassis may have a holding bag located at the bottom thereof that can be unfolded to hold the electronic device of the invention in a folded condition to facilitate protection and storing.

The foregoing, as well as additional objects, features and advantages of the invention will be more readily apparent from the following detailed description, which proceeds with reference to the accompanying drawings.

### BRIEF DESCRIPTION OF THE DRAWINGS

FIG. 1 is an exploded view of the invention.

FIG. 2 is a schematic view of an embodiment of the invention.

FIG. 3 is a perspective view of the invention in folding condition-1.

FIG. 4 is a perspective view of the invention in folding condition-2.

FIG. 5 is a perspective view of the invention in folding condition-3.

FIG. 6 is a perspective view of the invention in folding condition-4.

FIG. 7 is a fragmentary perspective view of the flexible screen and first chassis of the invention.

FIG. 8 is a fragmentary sectional view of the flexible screen and first chassis of the invention.

FIG. 9 is a schematic view of an embodiment of the invention equipped with a holding bag.

FIG. 10 is a sectional view of the invention held in the holding bag.

### DESCRIPTION OF THE PREFERRED EMBODIMENTS

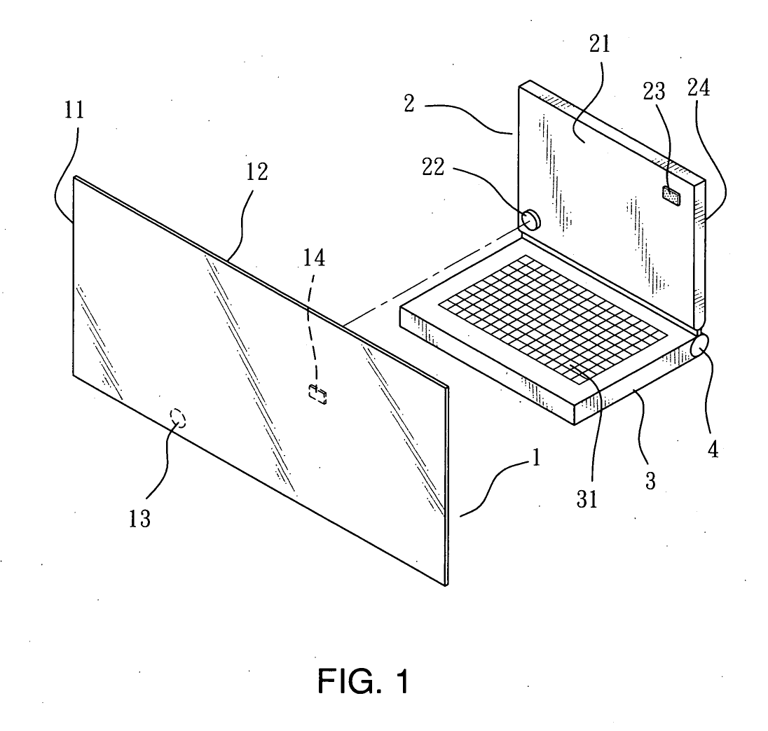

Please refer to FIG. 1 for an embodiment of the invention formed in a computer structure. It includes a flexible screen 1, a first chassis 2 and a second chassis 3.

The flexible screen 1 is rectangular and has two shorter sides 11 and two longer sides 12. The shorter sides 11 are formed at a length slightly smaller than the wide of the first chassis 2 and the second chassis 3. The flexible screen 1 has a stub shaft 13 formed thereon for turning.

The first chassis 2 has a first side 21 which is a plane to flatly hold the flexible screen 1 and has a vertical holding shaft 22 located thereon to be coupled with the stub shaft 13 of the flexible screen 1. The first chassis 2 also has a second side 24 opposing the flexible screen 1.

The second chassis 3 has an operation interface 31 and is coupled with the first chassis 2 through an axle 4.

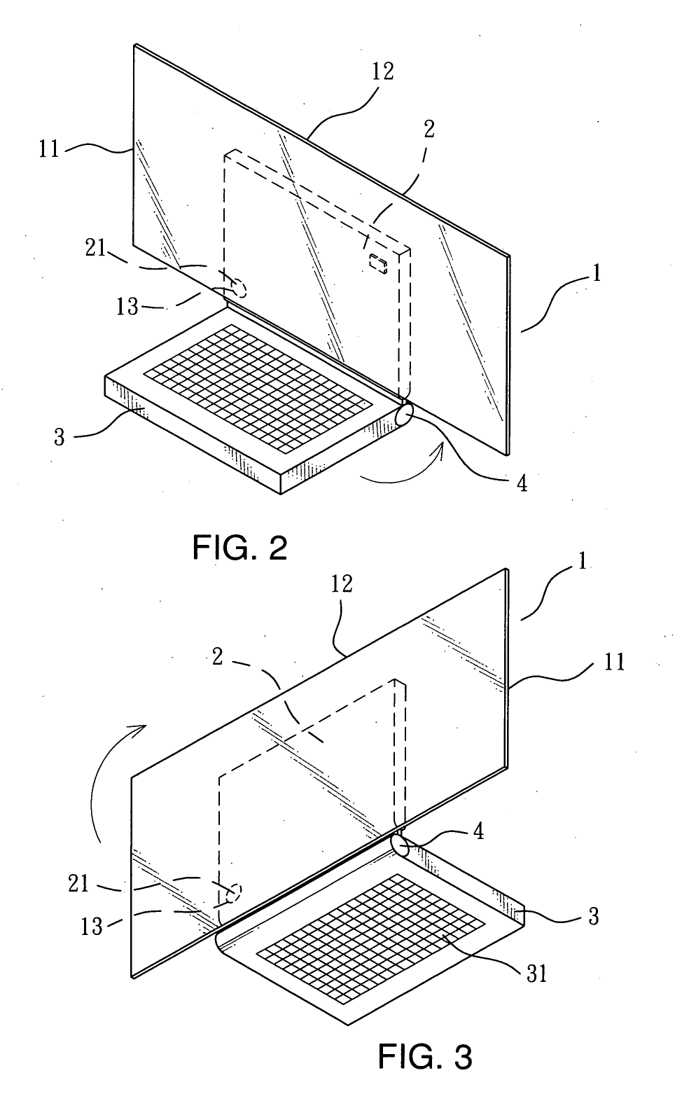

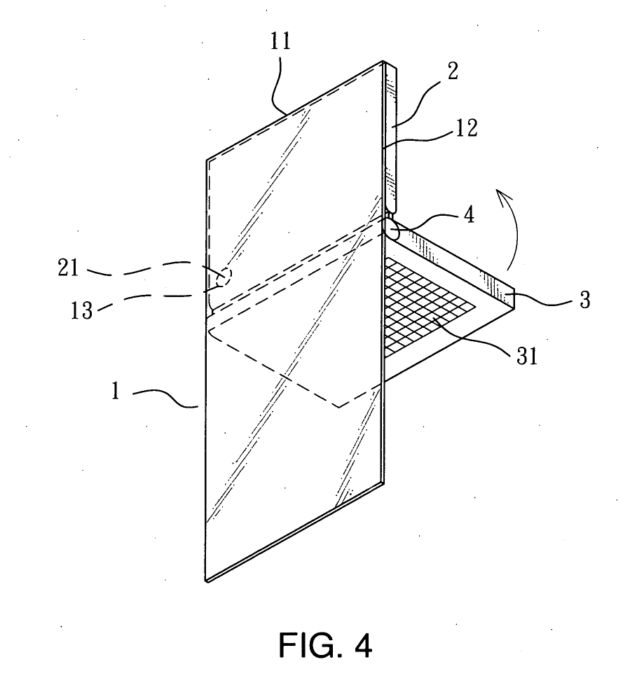

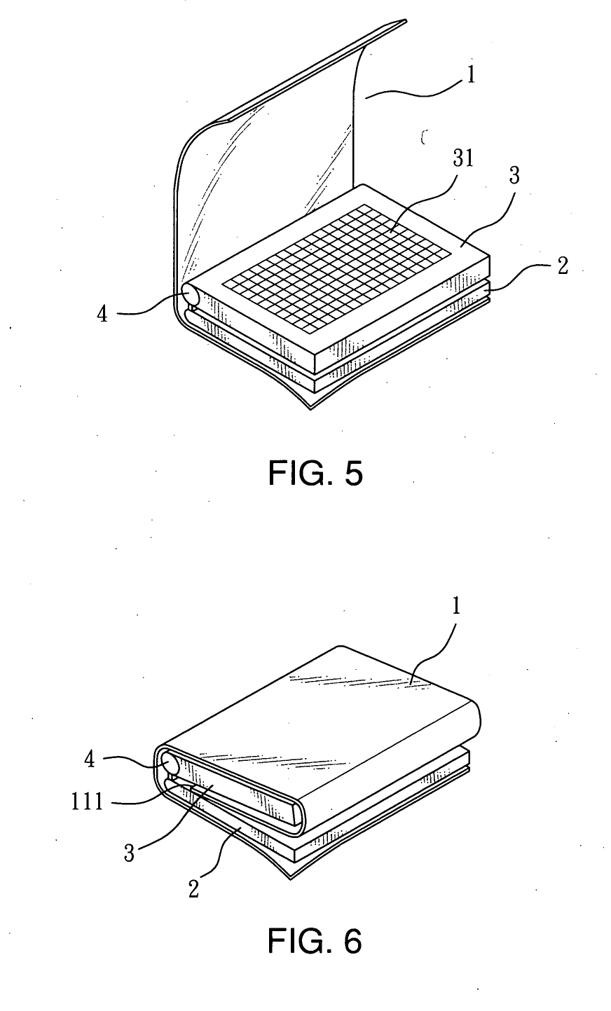

By means of the structure set forth above, when the invention is in a folding condition (referring to FIGS. 2 through 6), the second chassis 2 is turned backwards about the axle 4 towards the second side 24 of the first chassis 2; the flexible screen 1 is turned about the axis formed by the coupled stub shaft 13 and vertical holding shaft 22 for 90 degrees to align the shorter sides 11 with lateral sides of the first and second chassis 2 and 3. Then the first and second chassis 2 and 3 can be wrapped by the flexible screen 1 along the longer sides 12 with a distal end 111 of the flexible screen 1 interposed between the first and second chassis 2 and 3 to form a rolled up and folding condition.

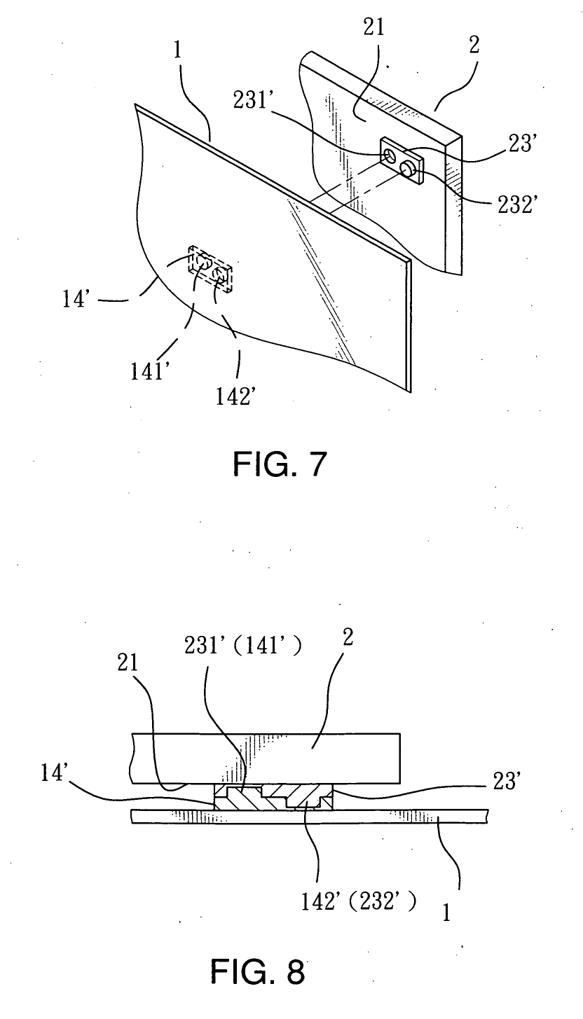

When in use with the flexible screen 1 and the first chassis 2 in an unfolded condition, the flexible screen 1 can be bonded and anchored on the first side 21 at a corresponding bonding area. The first chassis 2 and the flexible screen 1 have respectively at least one anchor element 23 and 14 located on the bonding area. The anchor element 23 and 14 is a Velcro band (as shown in FIG. 1), or one or more latch element 23′ and 14′ (as shown in FIGS. 7 and 8). The latch elements 23′ and 14′ have respectively a trough 231′ and 142′, and anchor struts 141′ and 232′ that are corresponding to and engageable with each other to anchor the flexible screen 1 on the first chassis 2.

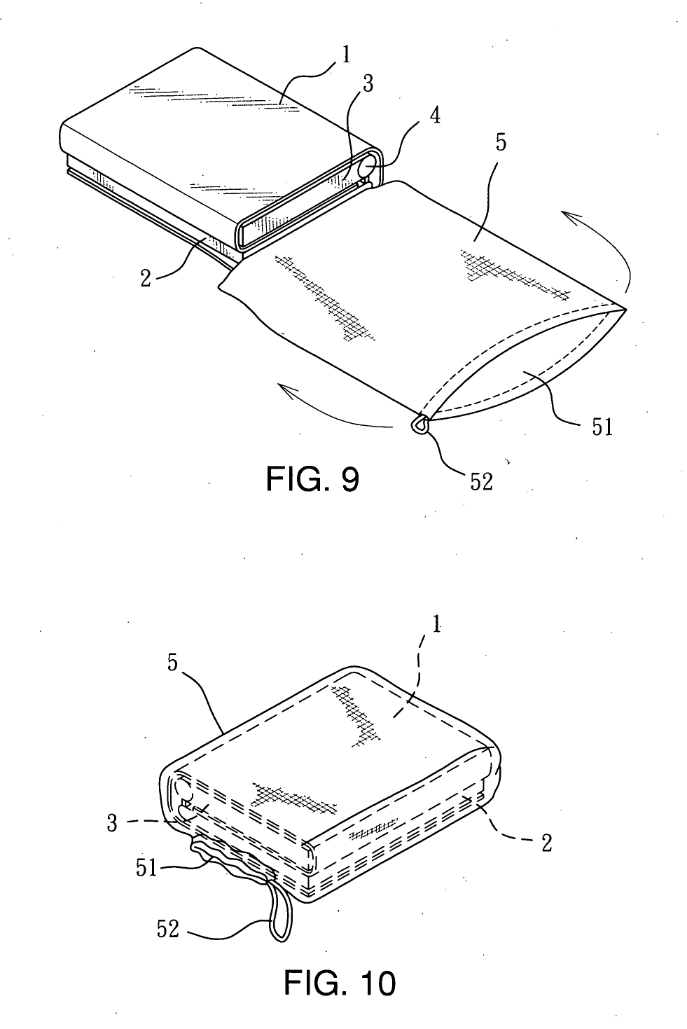

The invention may further have a holding bag 5 located at the bottom of the second chassis 3 (referring to FIGS. 9 and 10) that has an opening 51 and a tying element 52. After the invention is folded, the holding bag 5 can be unfolded to encase the invention to facilitate protection and storing.

As a conclusion, the invention in addition to making rolling of the flexible screen easier, also can greatly reduce the size of the device. It provides a significant improvement for the existing products.

While the preferred embodiments of the invention have been set forth for the purpose of disclosure, modifications of the disclosed embodiments of the invention as well as other embodiments thereof may occur to those skilled in the art. Accordingly, the appended claims are intended to cover all embodiments which do not depart from the spirit and scope of the invention.

I claim:

1. An electronic device having a foldable screen comprising a flexible screen, a first chassis and a second chassis, wherein:
the flexible screen is rectangular and has two shorter sides and two longer sides and a stub shaft located thereon for turning;
the first chassis has a first side formed a plane to flatly hold the flexible screen and a vertical holding shaft located on the first side to couple with the stub shaft of the flexible screen; and
the second chassis has an operation interface and is coupled with the first chassis through an axle;
wherein the first chassis and the second chassis are foldable together and the flexible screen is turnable about an axis formed by the coupled stub shaft and the vertical holding shaft for 90 degrees to align the shorter sides with lateral sides of the first chassis and the second chassis to wrap the folded first chassis and the second chassis along the longer sides.

2. The electronic device of claim 1, wherein the flexible screen and the first chassis have respectively a corresponding bonding area which has at least one anchor element located thereon.

3. The electronic device of claim 2, wherein the anchor element is a Velcro band.

4. The electronic device of claim 2, wherein the anchor element is a latch element.

5. The electronic device of claim 1 further having a holding bag located at the bottom of the second chassis.

6. The electronic device of claim 1, wherein the shorter sides of the screen are formed at a length slightly smaller than the width of the first chassis and the second chassis.
